(19) United States
(12) Patent Application Publication
(10) Pub. No.: US 2026/0057921 A1
(43) Pub. Date: Feb. 26, 2026

(54) MAGNETIC MEMORY DEVICE

(71) Applicant: Kioxia Corporation, Tokyo (JP)

(72) Inventors: Masahiro KOIKE, Yokohama Kanagawa (JP); Nobuyuki UMETSU, Kawasaki Kanagawa (JP); Tian LI, Yokohama Kanagawa (JP); Toshiya MURAKAMI, Meguro Tokyo (JP); Masatoshi YOSHIKAWA, Setagaya Tokyo (JP)

(21) Appl. No.: 19/075,664

(22) Filed: Mar. 10, 2025

(30) Foreign Application Priority Data
Aug. 23, 2024 (JP) 2024-141996

(51) Int. Cl. G11C 11/16; H10B 61/00; H10N 50/10; H10N 50/85

(52) U.S. Cl. CPC G11C 11/1675; G11C 11/161; H10B 61/10; H10N 50/10; H10N 50/85

(57) ABSTRACT

A magnetic memory device includes a conductive layer, a magnetoresistive effect element provided on the conductive layer and including a first end portion that contacts the conductive layer and a second end portion that is opposite to the first end portion, and a control circuit configured to perform a write operation to write data into the magnetoresistive effect element. The write operation including, in a first period, causing a current to flow in the conductive layer, and in a second period subsequent to the first period, stopping the current and applying a negative voltage to the second end portion with respect to the first end portion.

### CROSS-REFERENCE TO RELATED APPLICATIONS

This application is based upon and claims the benefit of priority from Japanese Patent Application No. 2024-141996, filed Aug. 23, 2024, the entire contents of which are incorporated herein by reference.

FIELD Embodiments described herein relate generally to a magnetic memory device.

### BACKGROUND

A magnetic memory device that uses a magnetoresistive effect element as a storage element is known. Various methods have been proposed as methods for writing data into a magnetoresistive effect element.

### BRIEF DESCRIPTION OF THE DRAWINGS

FIG. 1 is a block diagram illustrating a configuration of a magnetic memory device according to an embodiment.

FIG. 2 is a circuit diagram illustrating a circuit configuration of a memory cell array of the magnetic memory device.

FIG. 3 is a sectional view illustrating a structure of a magnetoresistive effect element shown in FIG. 2 and wiring in the vicinity thereof.

FIG. 4 is a waveform diagram illustrating reversal of the magnetization of a storage layer in a write operation performed by the magnetic memory device.

FIG. 5 is a circuit diagram illustrating voltages applied during a write operation performed by the magnetic memory device.

FIG. 6 is a circuit diagram illustrating voltages applied during a write operation performed by the magnetic memory device.

FIG. 7 is a flow chart illustrating a sequence of a write operation performed by the magnetic memory device.

FIG. 8 is a diagram illustrating a VCMA effect that occurs in a storage layer during a write operation performed by the magnetic memory device.

FIG. 9 shows sectional views illustrating a write operation performed by the magnetic memory device.

FIG. 10 shows sectional views illustrating a write operation performed by the magnetic memory device.

FIG. 11 is a waveform diagram illustrating a first example of a write operation performed by the magnetic memory device.

FIG. 12 is a waveform diagram illustrating a second example of a write operation performed by the magnetic memory device.

FIG. 13 is a waveform diagram illustrating a third example of a write operation performed by the magnetic memory device.

FIG. 14 is a waveform diagram illustrating a fourth example of a write operation performed by a magnetic memory device according to a modification.

FIG. 15 is a waveform diagram illustrating a fifth example of a write operation performed by a magnetic memory device according to a modification.

### DETAILED DESCRIPTION

Embodiments provide a magnetic memory device that shortens a write time.

According to one embodiment, a magnetic memory device comprises a conductive layer; a magnetoresistive effect element provided on the conductive layer and including a first end portion that contacts the conductive layer and a second end portion that is opposite to the first end portion; and a control circuit configured to perform a write operation to write data into the magnetoresistive effect element. The write operation includes, in a first period, causing a current to flow in the conductive layer; and in a second period subsequent to the first period, stopping the current and applying a negative voltage to the second end portion with respect to the first end portion.

Hereinafter, several embodiments will be described with reference to the accompanying drawings. In the following description, components having the same function and configuration will be denoted by a common reference symbol. Further, when distinguishing between a plurality of components that have a common reference symbol, an additional symbol is added after the common reference symbol. When there is no particular need to distinguish between a plurality of components, only a common reference symbol is assigned to the plurality of components, and an additional symbol is not added. The additional symbols are not limited to subscripts and superscripts, and include, for example, a lowercase alphabetical character added to the end of the reference symbol, a symbol, and an index indicating an array and the like.

### 1. Configuration

First, a configuration of a magnetic memory device 1 according to an embodiment will be described. For example, the magnetic memory device 1 is a magnetoresistive random access memory (MRAM). The magnetic memory device 1 includes a magnetoresistive effect element as a storage element. The magnetoresistive effect element is a variable resistance element that has a magnetoresistance effect produced by a magnetic tunnel junction (MTJ). The magnetoresistive effect element is also referred to as an “MTJ element”.

### 1.1 Magnetic Memory Device

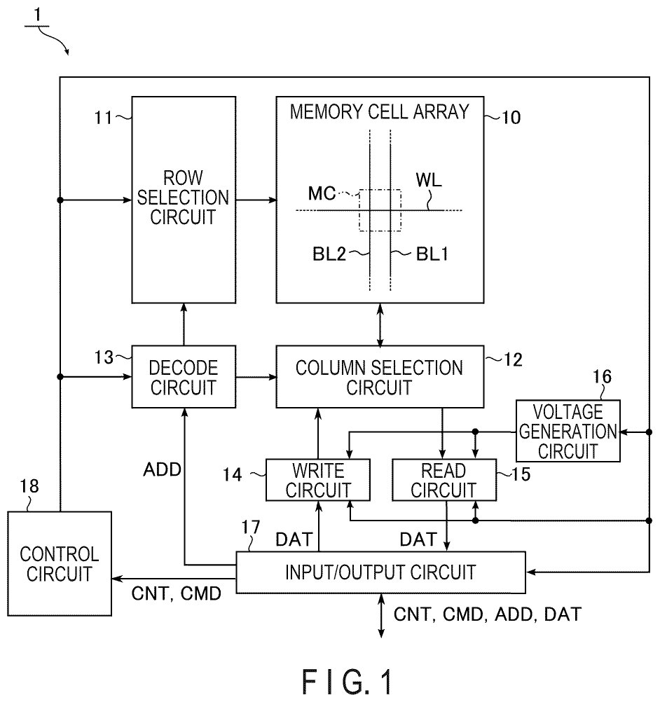

FIG. 1 is a block diagram illustrating a configuration of the magnetic memory device 1. The magnetic memory device 1 includes a memory cell array 10, a row selection circuit 11, a column selection circuit 12, a decode circuit 13, a write circuit 14, a read circuit 15, a voltage generation circuit 16, an input/output circuit 17, and a control circuit 18.

The memory cell array 10 is a storage unit for data in the magnetic memory device 1. The memory cell array 10 includes a plurality of memory cells MC. Each of the plurality of memory cells MC is associated with a set of a row and a column. The memory cells MC that are in the same row are connected to the same word line WL, and the memory cells MC that are in the same column are connected to the same set of a first bit line BL1 and a second bit line BL2.

The row selection circuit 11 is a circuit for selecting a row of the memory cell array 10. The row selection circuit 11 is connected to the memory cell array 10 via word lines WL. A decoding result (i.e., a row address) obtained by decoding an address ADD is supplied to the row selection circuit 11 from the decode circuit 13. The row selection circuit 11 selects a word line WL corresponding to a row based on the decoding result obtained by decoding the address ADD. Hereinafter, word lines WL other than the selected word line WL are referred to as “non-selected word lines WL”.

The column selection circuit 12 is a circuit for selecting a column of the memory cell array 10. The column selection circuit 12 is connected to the memory cell array 10 through first bit lines BL1 and second bit lines BL2. A decoding result (i.e., a column address) obtained by decoding an address ADD is supplied to the column selection circuit 12 from the decode circuit 13. The column selection circuit 12 selects a first bit line BL1 and a second bit line BL2 corresponding to a column based on the decoding result obtained by decoding of the address ADD. Hereinafter, first bit lines BL1 other than the selected bit line BL1 and second bit lines BL2 other than the selected bit line BL2 are referred to as “non-selected bit lines BL1” and “non-selected bit lines BL2”, respectively.

The decode circuit 13 is a decoder for decoding the address ADD from the input/output circuit 17. The decode circuit 13 supplies a signal indicating a decoding result obtained by decoding the address ADD to the row selection circuit 11 and the column selection circuit 12. The address ADD includes a column address and a row address.

The write circuit 14 includes, for example, a write driver (not illustrated). The write circuit 14 writes data into the memory cells MC.

The read circuit 15 includes, for example, a sense amplifier (not illustrated). The read circuit 15 reads data from the memory cells MC.

The voltage generation circuit 16 generates voltages for various operations of the memory cell array 10 using a power supply voltage provided from outside (not illustrated) the magnetic memory device 1. For example, the voltage generation circuit 16 generates various voltages required when performing a write operation, and outputs the voltages to the write circuit 14. Further, for example, the voltage generation circuit 16 generates various voltages required when performing a read operation, and outputs the voltages to the read circuit 15.

The input/output circuit 17 controls communication with the outside of the magnetic memory device 1. The input/output circuit 17 transfers an address ADD received from the outside of the magnetic memory device 1 to the decode circuit 13. The input/output circuit 17 transfers a command CMD received from the outside of the magnetic memory device 1 to the control circuit 18. The input/output circuit 17 performs operations to send and receive various control signals CNT which the control circuit 18 sends to and receives from the outside of the magnetic memory device 1. The input/output circuit 17 transfers data DAT from the outside of the magnetic memory device 1 to the write circuit 14, and outputs data DAT transferred from the read circuit 15 to the outside of the magnetic memory device 1.

The control circuit 18 includes, for example, a processor such as a central processing unit (CPU), a read only memory (ROM), and a random access memory (RAM). The control circuit 18 controls operations of the row selection circuit 11, the column selection circuit 12, the decode circuit 13, the write circuit 14, the read circuit 15, the voltage generation circuit 16, and the input/output circuit 17 in the magnetic memory device 1 based on the control signal CNT and the command CMD.

### 1.2 Memory Cell Array

Next, the configuration of the memory cell array of the magnetic memory device 1 will be described.

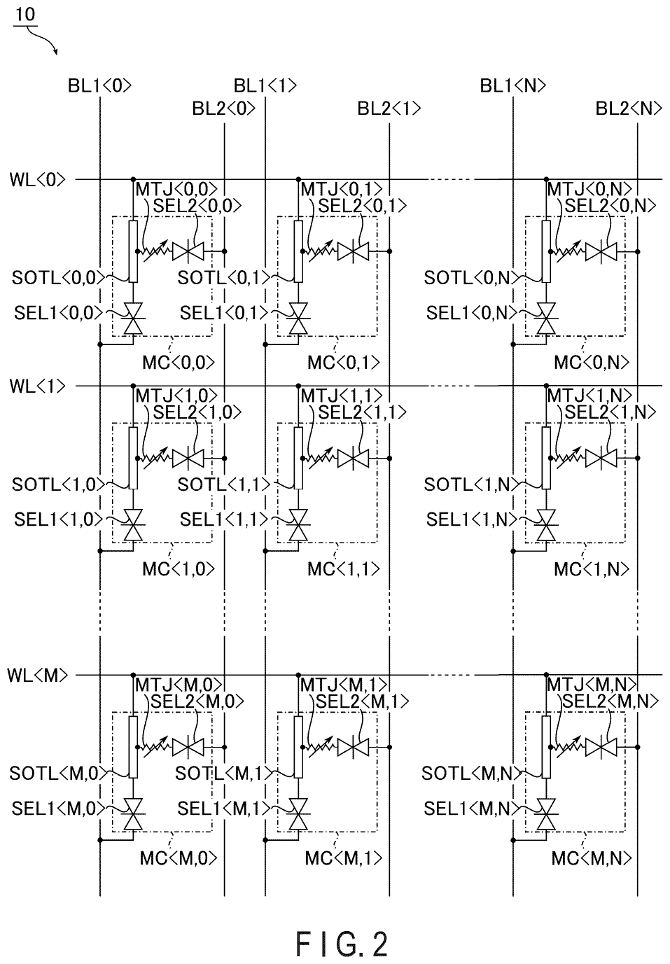

FIG. 2 is a circuit diagram illustrating a circuit configuration of the memory cell array. In FIG. 2, the word lines WL, the first bit lines BL1, and the second bit lines BL2 are illustrated, respectively, being distinguished by appended symbols including an index number (“< >”).

The memory cell array 10 includes a plurality of memory cells MC, a plurality of word lines WL, a plurality of first bit lines BL1, and a plurality of second bit lines BL2. In the example illustrated in FIG. 2, the plurality of memory cells MC include (M+1)×(N+1) memory cells, MC<0,0>, MC<0,1>, . . . , MC<0,N>, MC<1,0>, . . . , and MC<M,N> where each of M and N is an integer equal to or greater than 2. Although the example in FIG. 2 illustrates a case where each of M and N is an integer equal to or greater than 2, the embodiment is not limited to this example. M and N may also be 0 or 1. The plurality of word lines WL include (M+1) word lines, WL<0>, WL<1>, . . . , and WL<M>. The plurality of first bit lines BL1 include (N+1) first bit lines, BL1<0>, WBL<1>, and WBL<N>. The plurality of second bit lines BL2 include (N+1) second bit lines, BL2<0>, RBL<1>, . . . , and RBL<N>.

A plurality of memory cells MC are arranged in a matrix pattern within the memory cell array 10. A memory cell MC is associated with a set composed of one of the plurality of word lines WL and one set of a first bit line BL1 and a second bit line BL2 among the plurality of first bit lines BL1 and the plurality of second bit lines BL2. In other words, memory cell MC<i,j>(0≤i≤M, 0≤j≤N) is connected to word line WL<i>, first bit line BL1<j>, and second bit line BL2<j>.

The memory cell MC<i,j> is a three-terminal type memory cell having a first end connected to the word line WL<i>, a second end connected to the first bit line BL1<j>, and a third end connected to the second bit line BL2<j>. The memory cell MC<i,j> includes switching elements SEL1<i,j> and SEL2<i,j>, a magnetoresistance effect element MTJ<i,j>, and wiring SOTL<i,j>.

The wiring SOTL<i,j> includes a first portion, a second portion, and a third portion that is disposed between the first portion and the second portion. The first portion of the wiring SOTL<i,j> is connected to the word line WL<i>. The second portion of the wiring SOTL<i,j> is connected to the first bit line BL1<j>. The third portion of the wiring SOTL<i,j> is connected to the second bit line BL2<j>. The switching element SEL1<i,j> is connected between the second portion of the wiring SOTL<i,j> and the first bit line BL1<j>. A magnetoresistive effect element MTJ<i,j> is connected between the third portion of the wiring SOTL<i,j> and the second bit line BL2<j>. The switching element SEL2<i,j> is connected between the magnetoresistive effect element MTJ<i,j> and the second bit line BL2<j>.

The switching elements SEL1 and SEL2 are two-terminal type switching elements. A two-terminal type switching element differs from a three-terminal type switching element such as a transistor in that the two-terminal type switching element does not include a third terminal. When the voltage applied between the two terminals is less than threshold voltages Vth1 and Vth2, respectively, the switching elements SEL1 and SEL2 are in a “high resistance” state or “OFF” state, for example, in an electrically non-conductive state. When the voltage applied between the two terminals is equal to or higher than the threshold voltages Vth1 and Vth2, respectively, the switching elements SEL1 and SEL2 transition to a “low resistance” state or “ON” state, for example, to an electrically conductive state. More specifically, for example, if a voltage applied to a corresponding memory cell MC is lower than the threshold voltages Vth1 and Vth2, each of the switching elements SEL1 and SEL2 interrupts a current (i.e., turns to an OFF state), thereby functioning as an insulator with a large resistance value. If a voltage applied to a corresponding memory cell MC exceeds the threshold voltages Vth1 and Vth2, each of the switching elements SEL1 and SEL2 allows a current to flow through (i.e., turns to an ON state), thereby functioning as an insulator with a small resistance value. Regardless of the polarity of the voltage applied between the two terminals (i.e., regardless of the direction of the current flowing between the two terminals), the switching elements SEL1 and SEL2 switch between either allowing a current to flow or interrupting the current according to the magnitude of the voltage applied to the corresponding memory cell MC.

The wiring SOTL is a current path in the memory cell MC. For example, when the switching element SEL1 is in an ON state and the switching element SEL2 is in an OFF state, the wiring SOTL functions as a current path between the word line WL and the first bit line BL1. Further, for example, when the switching element SEL1 is in an OFF state and the switching element SEL2 is in an ON state, a part of the wiring SOTL functions as a current path between the word line WL and the second bit line BL2.

The magnetoresistive effect element MTJ is a variable resistance element. Based on a current whose path is controlled by the switching elements SEL1 and SEL2, the magnetoresistive effect element MTJ can switch a resistance value between a low resistance state and a high resistance state. The magnetoresistance effect element MTJ functions as a storage element that stores data in a nonvolatile manner by changing the resistance state thereof.

### 1.3 Magnetoresistive Effect Element and Wiring in Vicinity Thereof

Next, the configuration of a magnetoresistive effect element and wiring in the vicinity thereof in the magnetic memory device 1 is described.

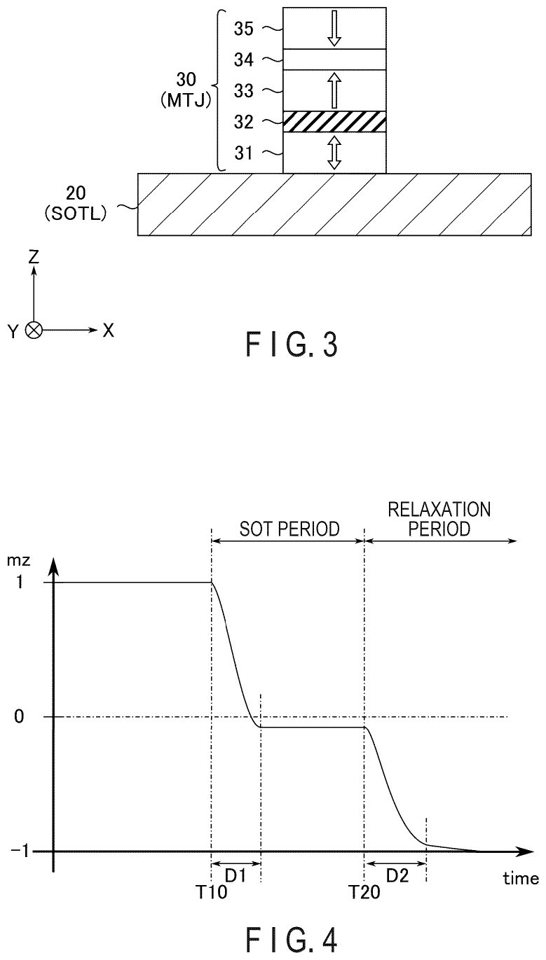

FIG. 3 is a sectional view illustrating the sectional structure of a magnetoresistive effect element and the wiring in the vicinity thereof according to an embodiment. As illustrated in FIG. 3, the wiring SOTL includes a conductive layer 20. The magnetoresistive effect element MTJ includes a stacked structure 30. The stacked structure 30 includes a ferromagnetic layer 31, a nonmagnetic layer 32, a ferromagnetic layer 33, a nonmagnetic layer 34, and a ferromagnetic layer 35.

Hereunder, the stacking direction of the stacked structure 30 is defined as “Z direction”. A plane orthogonal to the Z direction is defined as “XY-plane”. The direction in which the conductive layer 20 extends in the XY-plane is defined as “X direction”. The direction intersecting with the X direction in the XY-plane is defined as “Y direction”.

First, the configuration of the conductive layer 20 will be described.

The conductive layer 20 is a conductive film containing a heavy metal having non-magnetic properties. The conductive layer 20 contains, as a heavy metal, at least one element selected from, for example, tantalum (Ta), tungsten (W), ruthenium (Ru), rhodium (Rh), palladium (Pd), silver (Ag), copper (Cu), osmium (Os), iridium (Ir), platinum (Pt), gold (Au), gold (Au), and manganese (Mn). The element contained as a heavy metal in the conductive layer 20 may contain an oxide. Further, in a case where tantalum (Ta) or tungsten (W) is contained, the structure of the element is preferably a β structure. In the conductive layer 20, spin orbit torque (SOT) which is mainly due to the bulk spin Hall effect is generated by a current flowing inside the conductive layer 20. Further, in some cases, a spin effect may be caused that is due to the spin-splitter effect. The spin orbit torque acts on the ferromagnetic layer 31.

Next, the configuration of the stacked structure 30 will be described.

The ferromagnetic layer 31 is provided at the central part on the upper surface of the conductive layer 20. The ferromagnetic layer 31 is a conductive film having ferromagnetic properties. The ferromagnetic layer 31 is used as a storage layer. The ferromagnetic layer 31 has an axis of easy magnetization in a direction perpendicular to the film surface (i.e., Z direction). A spin orbit torque generated in the conductive layer 20 acts on the ferromagnetic layer 31. The ferromagnetic layer 31 is configured so that the magnetization direction of the ferromagnetic layer 31 is reversed when a spin orbit torque of a predetermined magnitude acts thereon.

The ferromagnetic layer 31 is generally a ferromagnetic layer that uses at least one element selected from cobalt (Co), iron (Fe), and nickel (Ni). A cobalt-iron (CoFe) alloy, iron (Fe), cobalt iron boron (CoFeB), iron boron (FeB), cobalt boron (CoB), and cobalt iron nickel boron (CoFeNiB) and the like are typical ferromagnetic layers having perpendicular magnetization. These have a body-centered cubic structure (bcc structure). Phosphorous (P) and carbon (C) and the like may be mentioned as elements that can substitute for boron (B). A magnetic material such as the aforementioned CoFeB generates perpendicular magnetic anisotropy at the interface by coming into contact with an oxide having a NaCl (001) structure. A typical example thereof is a MgO (001)/CoFeB stacked structure or the like.

The ferromagnetic layer 31 further contains a noble metal. The ferromagnetic layer 31 contains, as a noble metal, at least one element selected from, for example, gold (Au), silver (Ag), platinum (Pt), palladium (Pd), rhodium (Rh), iridium (Ir), ruthenium (Ru), and osmium (Os). Among these elements, platinum (Pt), palladium (Pd), rhodium (Rh), iridium (Ir), ruthenium (Ru), and osmium (Os) are preferable. From the viewpoint of improving a VCMA effect to be described later, iridium (Ir) is the most preferable. Preferably the ferromagnetic layer 31 contains the aforementioned noble metal in an amount equivalent to 50 at% or less. This is because if the ferromagnetic layer 31 contains the aforementioned noble metal in an amount greater than 50 at%, there is a possibility that magnetic properties of the ferromagnetic layer 31 will be degraded. In other words, in a case where the ferromagnetic layer 31 contains the aforementioned noble metal in an amount greater than 50 at%, there is a possibility that the saturation magnetization Ms and the magnetic anisotropy energy Ku of the ferromagnetic layer 31 will extremely decrease. Further, more preferably a concentration gradient with respect to the concentration of the aforementioned noble metal in the ferromagnetic layer 31 is a concentration gradient in which the concentration is higher on the side closer to the nonmagnetic layer 32. The concentration gradient can be detected by nano EDX (energy dispersive X-ray spectroscopy) analysis or nano EELS (electron energy loss spectroscopy) or the like.

The ferromagnetic layer 31 has a function of producing a VCMA (voltage-controlled magnetic anisotropy) effect at the interface with the nonmagnetic layer 32 that is described above. The VCMA effect is a phenomenon which changes an energy barrier Eb that is required for reversing magnetization of a magnetic material by application of a voltage. Note that although the VCMA effect physically changes the energy barrier Eb, when measuring the VCMA effect, a change in a coercive force Hc of the ferromagnetic layer 31 is measured as a measurement parameter. A decrease in the coercive force Hc means that the energy barrier Eb has decreased. The noble metal contained in the ferromagnetic layer 31 can increase the VCMA effect.

The nonmagnetic layer 32 is provided on the upper surface of the ferromagnetic layer 31. The nonmagnetic layer 32 is an insulating film having nonmagnetic properties. The nonmagnetic layer 32 is used as a tunnel barrier layer. The nonmagnetic layer 32 is provided between the ferromagnetic layer 31 and the ferromagnetic layer 33, and forms a magnetic tunnel junction in conjunction with these two ferromagnetic layers. Further, when an initial amorphous layer such as cobalt iron boron (CoFeB) is used as an interface layer of the ferromagnetic layer 31, the nonmagnetic layer 32 functions as a seed material that becomes a nucleus for growing a crystalline film from the interface with the ferromagnetic layer 31 in the crystallization process of the ferromagnetic layer 31. Similarly, in a case where cobalt iron boron (CoFeB) is used as the interface layer of the ferromagnetic layer 33, the nonmagnetic layer 32 also functions as a seed material for the ferromagnetic layer 33. Here, the initial amorphous layer is a layer that is in an amorphous state immediately after film formation and crystallizes after annealing treatment. The nonmagnetic layer 32 has a tetragonal or cubic structure in which a film surface is oriented in a (001) plane. Magnesium oxide (MgO) may be mentioned as an example of the oxide used for the nonmagnetic layer 32. Magnesium oxide (MgO) has a NaCl structure. When magnesium oxide (MgO) is used for the nonmagnetic layer 32, a (001) interface of magnesium oxide (MgO) and a (001) interface of cobalt iron boron (CoFeB) are matched with each other and crystals are grown by annealing. For this reason, the cobalt iron boron (CoFeB) becomes a (001)-oriented body-centered cubic structure. The nonmagnetic layer 32 may be an oxide other than magnesium oxide (MgO). In such case, a nonmagnetic layer for which a VCMA coefficient β, as described below, is large is desirable. When the VCMA coefficient β is large, the VCMA effect can be increased.

The ferromagnetic layer 33 is provided on the upper surface of the nonmagnetic layer 32. The ferromagnetic layer 33 is a conductive film having ferromagnetic properties. The ferromagnetic layer 33 is used as a reference layer. The ferromagnetic layer 33 has an axis of easy magnetization in a direction perpendicular to the film surface (i.e., Z direction). The magnetization direction of the ferromagnetic layer 33 is fixed. In the example shown in FIG. 3, the magnetization direction of the ferromagnetic layer 33 is in the direction toward the stacked structure 30 from the conductive layer 20. Note that the phrase “the magnetization direction is fixed” means that the magnetization direction is not changed by a torque large enough to reverse the magnetization direction of the ferromagnetic layer 31. Usually, an interface layer is used for the ferromagnetic layer 33. As the interface layer of the ferromagnetic layer 33, an initial amorphous layer such as cobalt iron boron (CoFeB) is used. In addition, an auxiliary ferromagnetic layer is provided so as to be in contact with a surface of the cobalt iron boron (CoFeB) layer that is the surface on the opposite side to a surface of the cobalt iron boron (CoFeB) layer in contact with the magnesium oxide (MgO) layer. The auxiliary ferromagnetic layer includes, for example, at least one alloy film selected from cobalt platinum (CoPt), cobalt nickel (CoNi), and cobalt palladium (CoPd). The auxiliary ferromagnetic layer is a stacked structure such as a Co/Pt stacked structure or a Co/Pd stacked structure. The cobalt iron boron (CoFeB) layer serving as the initial amorphous layer is used by being stacked with the aforementioned CoPt, CoPd, Co/Pt stacked structure, Co/Pd stacked structure or the like. In this case, in the interface layer of the ferromagnetic layer 33, for example, in the aforementioned CoFeB layer, a (001)-oriented MgO layer is formed closer to the nonmagnetic layer 32 side than the other layers.

The nonmagnetic layer 34 is provided on the upper surface of the ferromagnetic layer 33. The nonmagnetic layer 34 is a conductive film having non-magnetic properties. The nonmagnetic layer 34 is used as a spacer layer. The nonmagnetic layer 34 is composed of, for example, an element selected from ruthenium (Ru), osmium (Os), rhodium (Rh), iridium (Ir), vanadium (V), and chromium (Cr), or an alloy thereof. For example, the film thickness of the nonmagnetic layer 34 is equal to or less than 2 nm.

The ferromagnetic layer 35 is provided on the upper surface of the nonmagnetic layer 34. The ferromagnetic layer 35 is a conductive film having ferromagnetic properties. The ferromagnetic layer 35 is used as a shift cancelling layer. The ferromagnetic layer 35 has an axis of easy magnetization in a direction perpendicular to the film surface (Z direction). The ferromagnetic layer 35 includes at least one alloy layer selected from, for example, cobalt platinum (CoPt), cobalt nickel (CoNi), and cobalt palladium (CoPd). The ferromagnetic layer 35 may be a stacked structure such as a Co/Pt stacked structure or a Co/Pd stacked structure.

The ferromagnetic layer 33 and the ferromagnetic layer 35 are anti-ferromagnetically coupled by the nonmagnetic layer 34. That is, the ferromagnetic layer 33 and the ferromagnetic layer 35 are coupled so as to have magnetization directions that are anti-parallel to each other. Such kind of coupling structure between the ferromagnetic layer 33, the nonmagnetic layer 34, and the ferromagnetic layer 35 is referred to as a “synthetic anti-ferromagnetic (SAF) structure”. By having the SAF structure, the ferromagnetic layer 35 can offset the influence of the leakage magnetic field of the ferromagnetic layer 33 on the change in the magnetization direction of the ferromagnetic layer 31, and thereby reduce the substantial leakage magnetic field of the ferromagnetic layer 33.

The magnetoresistive effect element MTJ can take either one of a low resistance state and a high resistance state depending on whether the relative relationship between the magnetization directions of the storage layer and the reference layer is parallel or anti-parallel. Here, the magnetization direction of the storage layer with respect to the magnetization direction of the reference layer is controlled without causing a write current to flow through such a magnetoresistance effect element MTJ. Specifically, a writing method that utilizes a spin orbit torque generated by causing a current to flow through the wiring SOTL is adopted.

When a write current Ic0 of a certain magnitude is caused to flow through the wiring SOTL in the X direction, the relative relationship between the magnetization directions of the storage layer and the reference layer becomes parallel. In this parallel state, a resistance value of the magnetoresistive effect element MTJ becomes the lowest value, and the magnetoresistive effect element MTJ is set to a low resistance state. This low resistance state is called a “P (parallel) state”, and is defined as, for example, a state of data “0”.

Further, when a write current Ic1 is caused to flow through the wiring SOTL in the opposite direction to the write current Ic0, the relative relationship between the magnetization directions of the storage layer and the reference layer becomes anti-parallel. In this anti-parallel state, the resistance value of magnetoresistive effect element MTJ becomes the highest value, and the magnetoresistive effect element MTJ is set to a high resistance state. This high resistance state is called an “AP (anti-parallel) state”, and is defined as, for example, a state of data “1”.

Note that the manner of defining the data “1” and the data “0” is not limited to the example described above. For example, the P state may be defined as data “1”, and the AP state may be defined as data “0”.

The shape of the magnetoresistance effect element MTJ as viewed in the Z direction is an elliptic shape or a circular shape. From the viewpoint of high-density integration of the memory cells MC, a circular shape is preferable as the shape of the magnetoresistance effect element MTJ as viewed in the Z direction. From the viewpoint of reducing area size and reducing electricity consumption, the short-side length of the magnetoresistive effect element MTJ in the case of an elliptic shape, and the radius of the magnetoresistive effect element MTJ in the case of a circular shape are preferably 100 nm or less, respectively.

### 1.2 Write Operation

Next, a write operation performed by the magnetic memory device 1 will be described.

### 1.2.1 SOT Period and Relaxation Period

FIG. 4 is a waveform diagram illustrating the reversal of the magnetization of the storage layer in a write operation performed by the magnetic memory device 1. In the example illustrated in FIG. 4, time variations in a Z-direction component mz are illustrated by representing the Z-direction component mz in a case where the ordinate axis represents magnetization of the storage layer expressed as a unit vector, and the abscissa axis represents time.

Hereunder, for convenience in the description, it is assumed that a state in which the Z-direction component mz=1 indicates a state in which the magnetization direction of the storage layer is the direction toward the reference layer among the Z directions. Further, it is assumed that a state in which the Z-direction component mz=−1 indicates a state in which the magnetization direction of the storage layer is the direction toward the wiring SOTL among the Z directions. In other words, FIG. 4 illustrates a situation in which, in a case where the magnetization direction of the reference layer is the same as in FIG. 3, the magnetization direction of the storage layer is reversed so that the state of the magnetoresistive effect element MTJ changes from the P state to the AP state by a write operation.

As illustrated in FIG. 4, a write operation principally has an SOT period, and a relaxation period that follows the SOT period. In the example in FIG. 4, it is assumed that the Z-direction component mz of the magnetization direction of the storage layer is “1” until a time instant T10 is reached. An SOT period starts from the time instant T10.

The SOT period is a period in which a spin orbit torque is caused to act on the storage layer. By the spin orbit torque acting on the storage layer, the magnetization direction of the storage layer can be oriented to approximately the horizontal direction. Further, when the spin orbit torque is caused to act on the storage layer, a bias magnetic field Hx in the X direction is also applied to the wiring SOTL. By this means, the Z-direction component mz of the magnetization direction of the storage layer can be given the opposite polarity (in the example in FIG. 4, a negative Z-direction component) to the polarity of the Z-direction component before the SOT period. In other words, during the SOT period, the magnetization direction of the storage layer that had a component parallel to the magnetization direction of the reference layer before the write operation is tilted so as to have a component anti-parallel to the magnetization direction of the reference layer.

Here, during the SOT period, a positive VCMA effect is generated with respect to the storage layer. By this means, a time D1 required to tilt the Z-direction component mz of the magnetization direction of the storage layer from “1” to a negative value close to “0” can be shortened. The positive VCMA effect is described later.

Next, a relaxation period starts from a time instant T20. The relaxation period is a period during which the action of the spin orbit torque on the storage layer is stopped, and the magnetization direction of the storage layer is stabilized in the Z direction (i.e., the direction that is parallel or anti-parallel to the magnetization direction of the reference layer). As described above, the direction of the axis of easy magnetization of the storage layer is in the Z direction. Therefore, the magnetization direction of the storage layer which had been forcefully oriented to approximately the horizontal direction by the spin orbit torque, is oriented to the Z direction by stopping the action of the spin orbit torque on the storage layer.

Here, as described above, as a result of passing through the SOT period, the magnetization direction of the storage layer is tilted so as to have a component that is anti-parallel to the magnetization direction of the reference layer. Therefore, during the relaxation period, the magnetization direction of the storage layer easily tilts in a direction that is anti-parallel to the magnetization direction of the reference layer. When reversal of the magnetization direction of the storage layer is completed, the relaxation period ends.

Here, during the relaxation period, a negative VCMA effect is generated with respect to the storage layer. By this means, a time D2 required to tilt the Z-direction component mz of the magnetization direction of the storage layer from a negative value close to “0” to “−1” can be shortened. The negative VCMA effect is described later.

Data is written to the magnetoresistive effect element MTJ by the write operation described above.

### 1.2.2 Applied Voltages

### (SOT Period)

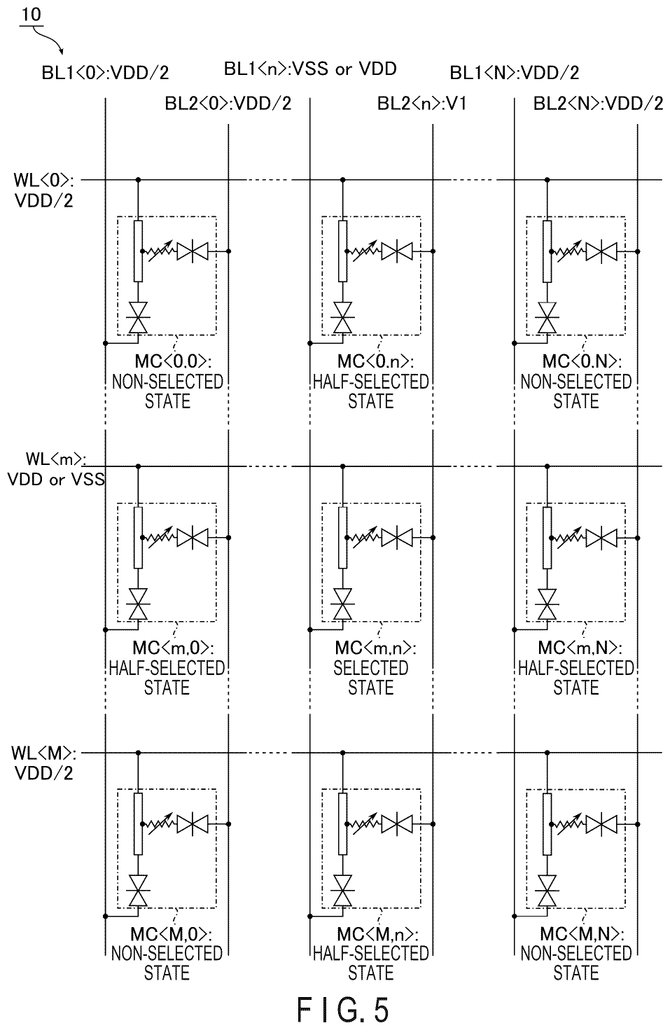

FIG. 5 is a circuit diagram illustrating voltages applied during a write operation performed by the magnetic memory device 1. FIG. 5 illustrates voltages applied to various kinds of wiring in the SOT period in a case where, among the plurality of memory cells MC, data is written to a memory cell MC<m,n>(0<m<M, 0<n<N).

When writing data to the memory cell MC<m,n>, in the SOT period a voltage VDD or VSS is applied to each of a word line WL<m> and a first bit line BL1<n>. If the voltage VDD is applied to the word line WL<m>, the voltage VSS is applied to the first bit line BL1<n>. If the voltage VSS is applied to the word line WL<m>, the voltage VDD is applied to the first bit line BL1<n>. A voltage V1 (=VDD/2+Vg1) is applied to a second bit line BL2<n>. Here, Vg1 is a positive real number. A voltage VDD/2 is applied to all the word lines WL other than the word line WL<m>, to all the first bit lines BL1 other than the first bit line BL1<n>, and to all the second bit lines BL2 other than the second bit line BL2<n>.

As a result, a potential difference VDD occurs between the word line WL<m> and the first bit line BL1<n>. In this case, a potential in a connecting part between wiring SOTL<m,n> and magnetoresistance effect element MTJ<m,n> is VDD/2. Therefore, in the second bit line BL2<n>, a positive potential difference Vg1 (>0) occurs with respect to the wiring SOTL<m,n>.

Further, a potential difference VDD/2 occurs between the word line WL<m> and an arbitrary first bit line BL1 other than the first bit line BL1<n>. A potential difference VDD/2 occurs between an arbitrary word line WL other than the word line WL<m> and the first bit line BL1<n>. A potential difference does not occur between an arbitrary word line WL other than the word line WL<m> and an arbitrary first bit line BL1 other than the first bit line BL1<n>. A potential difference that occurs between an arbitrary set of a wiring SOTL and a second bit line BL2 other than the set of the wiring SOTL<m,n> and the second bit line BL2<n> is less than |Vg1|.

Here, the voltage VSS is a reference potential. The voltage VSS is, for example, 0 V. The voltage VDD (or the potential difference VDD) with respect to the voltage VSS places the switching elements SEL1 and SEL2 in an ON state. The potential difference VDD/2 places the switching element SEL1 in an OFF state. The voltage V1 (or the potential difference Vg1) with respect to the voltage VDD/2 places the switching element SEL2 in an ON state. A potential difference that occurs between an arbitrary set of a wiring SOTL and a second bit line BL2 other than the set of the wiring SOTL<m,n> and the second bit line BL2<n> places the switching element SEL2 in an OFF state.

Therefore, the switching elements SEL1<m,n> and SEL2<m,n> enter an ON state. All switching elements SEL1 other than the switching element SEL1<m,n> enter an OFF state. All switching elements SEL2 other than the switching element SEL2<m,n> enter an OFF state.

Thus, the potential difference Vg1 can be applied to the magnetoresistive effect element MTJ<m,n> while also applying the potential difference VDD to the wiring SOTL<m,n>. By applying the potential difference VDD to the wiring SOTL, a current for changing the resistance state of the magnetoresistive effect element MTJ can be caused to flow. By applying the positive potential difference Vg1 to the magnetoresistive effect element MTJ, a positive VCMA effect can be caused to occur in the storage layer. Note that although a current also flows to the magnetoresistive effect element MTJ<m,n> as a result of the switching element SEL2 entering an ON state, the amount of the current is negligibly minute.

In the aforementioned SOT period, the state of the memory cell MC<m,n> may also be referred to as a “selected state”. The state of memory cells MC<0,n> to MC<m−1,n>, MC<m+1,n> to MC<M,n>, MC<m,0> to MC<m,n−1>, and MC<m,n+1> to MC<m,N> may also be referred to as a “half-selected state”. The state of all memory cells MC that are not in a selected state or a half-selected state may also be referred to as a “non-selected state”.

### (Relaxation Period)

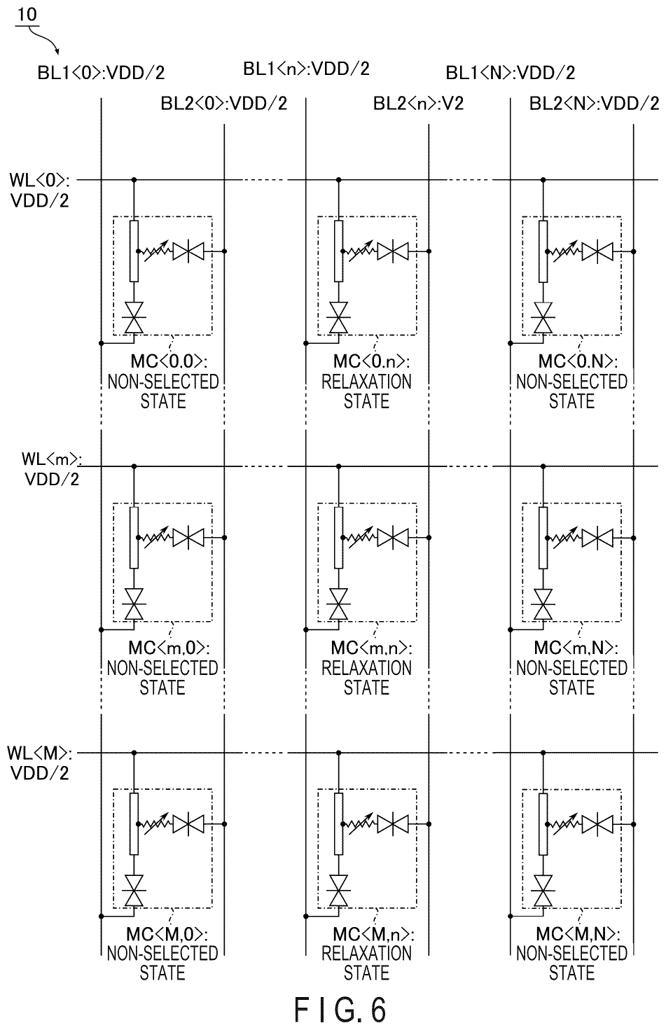

FIG. 6 is a circuit diagram illustrating voltages applied during a write operation performed by the magnetic memory device 1. FIG. 6 illustrates voltages applied to various kinds of wiring in the relaxation period in a case where, among the plurality of memory cells MC, data is written to a memory cell MC<m,n>.

When writing data to the memory cell MC<m,n>, in the relaxation period a voltage VDD/2 is applied to all the word lines WL, all the first bit lines BL1, and all the second bit lines BL2 other than a second bit line BL<n>. A voltage V2(=VDD/2+Vg2) is applied to the second bit line BL2<n>. Here, Vg2 is a negative real number.

As a result, a potential difference does not occur between all the word lines WL and all the first bit lines BL1<n>. Therefore, a potential difference with respect to the corresponding wiring SOTL does not occur in all the second bit lines BL2 other than the second bit line BL2<n>. On the other hand, in the second bit line BL2<n> a negative potential difference Vg2 (<0) occurs with respect to the respective wirings SOTL<0,n>, . . . , SOTL<m,n>, . . . , and SOTL<M,n>.

Here, the voltage V2 (or the potential difference Vg2) with respect to the voltage VDD/2 places the switching element SEL2 in an ON state.

Therefore, all the switching elements SEL1 enter an OFF state. The switching elements SEL2<0,n>, . . . , SEL2<m, n>, . . . , and SEL2<M, n> enter an ON state. All the switching elements SEL2 other than the switching elements SEL2<0,n>, . . . , SEL2<m,n>, . . . , and SEL2<M,n> enter an OFF state.

Thus, the potential difference Vg2 can be applied to the magnetoresistive effect element MTJ <m,n> without causing a potential difference to occur in the wiring SOTL<m,n>. By applying the negative potential difference Vg2 to the magnetoresistive effect element MTJ, a negative VCMA effect can be induced in the storage layer.

In the relaxation period described above, the state of the memory cells MC<0,n>, . . . , MC<m,n>, . . . , and MC<M,n> is also referred to as a “relaxation state”. The state of all memory cells MC that are not in a relaxation state is also referred to as a “non-selected state”.

### 1.2.3 Sequence of Write Operation

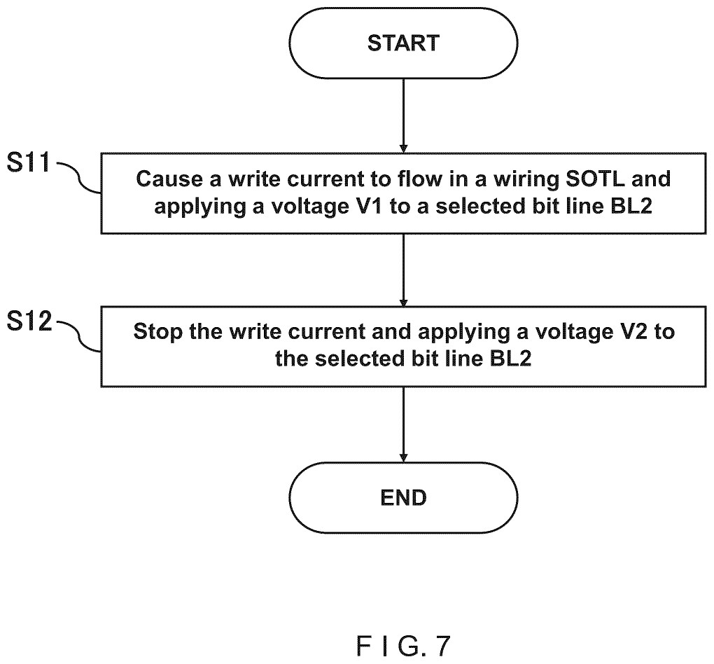

FIG. 7 is a flow chart illustrating a sequence of a write operation performed by the magnetic memory device 1.

The control circuit 18 of the magnetic memory device 1 starts a series of processes in FIG. 7 (START), for example, upon receipt from an externally located memory controller (not illustrated) of a signal to start a write operation and of address information of the memory cell MC to be written. The following description of the series of processes corresponds to the processes on the memory cell MC to be written.

First, in the SOT period, the control circuit 18 causes a write current (Ic0 or Ic1) to flow in the wiring SOTL and applies the voltage V1 to the selected bit line BL2 (S11). Note that the voltage V1 is applied to the selected bit line BL2 such that a positive potential difference Vg1 occurs to one end of the magnetoresistive effect element MTJ with respect to the other end connected to the wiring SOTL.

Next, in the relaxation period, the control circuit 18 stops the write current and applies the voltage V2 to the selected bit line BL2 (S12). Note that the voltage V2 is applied to the selected bit line BL2 such that a negative potential difference Vg2 occurs to the one end of the magnetoresistive effect element MTJ with respect to the other end connected to the wiring SOTL. Then, the control circuit 18 ends the series of processes in FIG. 7 (END).

### 1.2.4 VCMA Effect

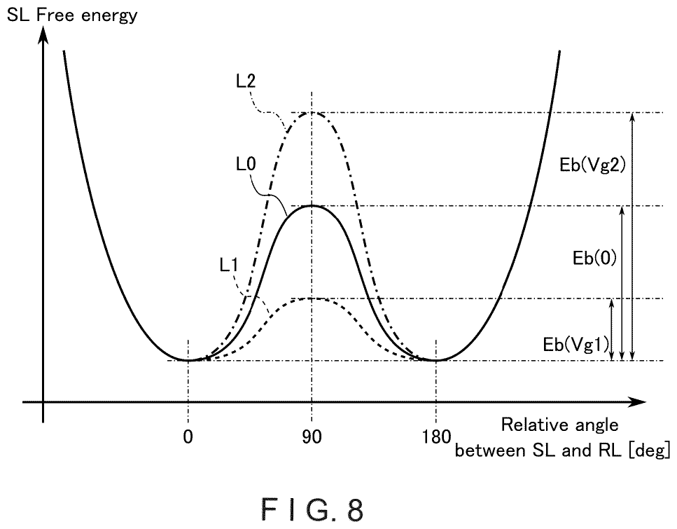

FIG. 8 is a diagram illustrating a VCMA effect that occurs in a storage layer during a write operation performed by the magnetic memory device 1. In FIG. 8, changes in the free energy curve of the storage layer depending on whether a VCMA effect occurs are illustrated by representing the relative angle of the magnetization direction vector between the storage layer and the reference layer (i.e., the magnetization direction of the storage layer relative to the magnetization direction of the reference layer as a reference) on the abscissa axis, and representing the free energy curve of the storage layer on the ordinate axis. Specifically, a solid line L0 corresponds to a case where a VCMA effect does not occur. A dashed line L1 corresponds to a case where a positive VCMA effect occurs. An alternate long and short dash line L2 corresponds to a case where a negative VCMA effect occurs.

As illustrated in FIG. 8, the free energy curve of the storage layer becomes lower in a case where the magnetization direction of the storage layer is parallel or anti-parallel to the magnetization direction of the reference layer. This corresponds to the fact that the magnetoresistive effect element MTJ is stable in the P state or the AP state. On the other hand, the free energy curve of the storage layer reaches a maximum in a case where the magnetization direction of the storage layer is oriented in the horizontal direction. This corresponds to the fact that an energy barrier Eb is present when the state of the magnetoresistive effect element MTJ changes from the P state to the AP state or from the AP state to the P state. The energy barrier Eb is also referred to as perpendicular magnetic anisotropy energy.

The energy barrier Eb is expressed as follows using the potential difference Vg applied to the magnetoresistive effect element MTJ.

Eb(Vg)=Eb(0)−βVg/t

In the expression, β represents the VCMA coefficient, and is a real number coefficient. Further, t represents the film thickness of the tunnel barrier layer.

As illustrated by the solid line L0 and the dashed line L1, when a positive potential difference Vg1 is applied to the magnetoresistive effect element MTJ (that is, to the second bit line BL2 with respect to the connecting portion with the magnetoresistive effect element MTJ of the wiring SOTL), an energy barrier Eb(Vg1) becomes lower relative to an energy barrier Eb(0). By this means, the energy that is required for reversing the magnetization of the storage layer can be reduced, and reversal of the magnetization of the storage layer can be promoted. In the present embodiment, modulation of the energy barrier Eb so as to promote reversal of the magnetization of the storage layer is referred to as “positive VCMA effect”.

On the other hand, as illustrated by the solid line L0 and the alternate long and short dash line L2, when a negative potential difference Vg2 is applied to the magnetoresistive effect element MTJ (that is, to the second bit line BL2 with respect to the connecting portion with the magnetoresistive effect element MTJ of the wiring SOTL), an energy barrier Eb(Vg2) becomes higher relative to the energy barrier Eb(0). By this means, the energy required for reversing the magnetization of the storage layer can be increased, and reversal of the magnetization of the storage layer can be inhibited. In the present embodiment, modulation of the energy barrier Eb so as to inhibit reversal of the magnetization of the storage layer is referred to as a “negative VCMA effect”.

### 1.2.5 Magnetization Reversal

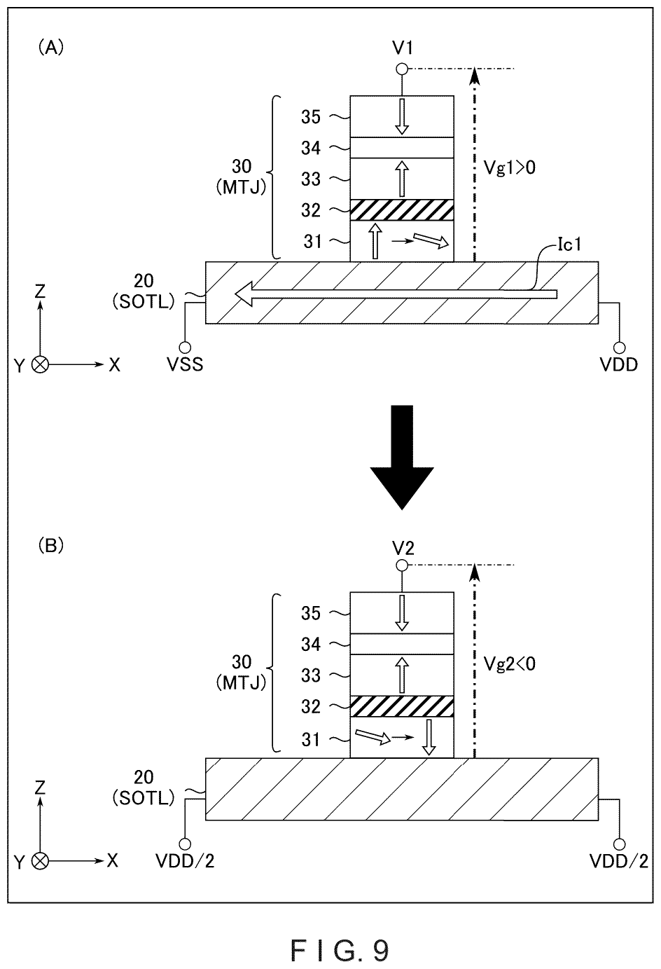

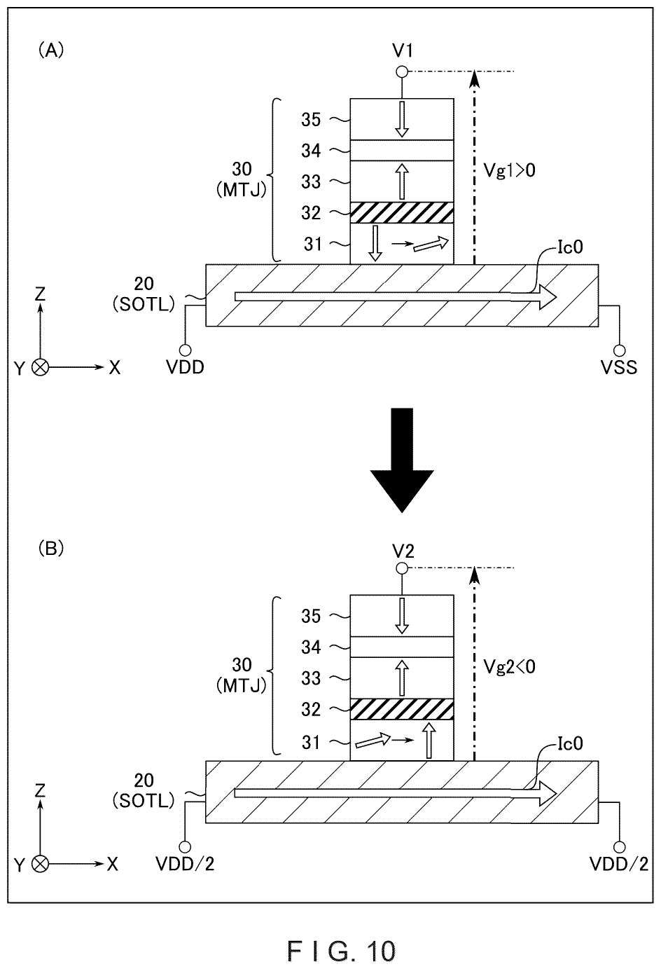

FIGS. 9 and 10 are sectional views illustrating a write operation performed by the magnetic memory device 1. In the parts (A) of FIGS. 9 and 10, a current flowing in a memory cell MC which is in a selected state in a SOT period, and a change in the magnetization direction of the magnetoresistive effect element MTJ are schematically illustrated. In the parts (B) of FIGS. 9 and 10, a change in the magnetization direction of the magnetoresistive effect element MTJ which is in a relaxation state in a relaxation period is schematically illustrated. FIG. 9 corresponds to a write operation when data “1” is written. FIG. 10 corresponds to a write operation when data “0” is written.

First, a write operation for writing data “1” will be described with reference to FIG. 9. In the example in FIG. 9, a case is illustrated where the write current Ic1 flows from a word line WL (i.e., the right side of the drawing) towards a first bit line BL1 (i.e., the left side of the drawing).

As illustrated in the part (A) of FIG. 9, in the SOT period, a potential difference VDD that places the switching element SEL1 in an ON state occurs between both ends of the wiring SOTL. By controlling the potential difference VDD, a write current Ic1 flows in the wiring SOTL. As a result of the write current Ic1 flowing in the wiring SOTL, a spin orbit torque that attempts to tilt the magnetization direction of the storage layer to the horizontal direction is generated. The spin orbit torque acts on the storage layer that is near to the wiring SOTL. Further, although not illustrated in FIG. 9, a bias magnetic field Hx in the X direction is applied to the storage layer.

Therefore, by the action of the spin orbit torque and the application of the bias magnetic field Hx, the magnetization direction of the storage layer is tilted in a direction which is approximately the horizontal direction and which has a component anti-parallel to the magnetization direction of the reference layer.

Further, a potential difference Vg1 such that the reference layer side becomes a high potential relative to the storage layer side occurs between both ends of the magnetoresistive effect element MTJ. As a result, a positive VCMA effect occurs and the energy barrier Eb of the storage layer decreases. Therefore, the magnetization direction of the storage layer is quickly tilted by the assistance of the positive VCMA effect.

Next, as illustrated in the part (B) of FIG. 9, in the relaxation period, a potential difference does not occur between both ends of the wiring SOTL. As a result, the write current Ic1 stops and the action of the spin orbit torque also ceases. During the SOT period, the state of the storage layer transitions to the AP state by exceeding the energy barrier Eb from the P state. Therefore, in the relaxation period, the magnetization direction of the storage layer tilts to a more stable state in the AP state (that is, a completely anti-parallel state with respect to the magnetization direction of the reference layer).

Further, a potential difference Vg2 such that the reference layer side becomes a low potential relative to the storage layer side occurs between both ends of the magnetoresistive effect element MTJ. As a result, a negative VCMA effect occurs and the energy barrier Eb of the storage layer increases. Therefore, the magnetization direction of the storage layer is tilted more quickly by the assistance of the negative VCMA effect.

By the above-described operation, the magnetization direction of the storage layer is reversed to a direction anti-parallel to the magnetization direction of the reference layer, and the operation for writing data “1” is completed.

Next, a write operation for writing data “0” will be described with reference to FIG. 10. In the example in FIG. 10, a case is illustrated where the write current Ic0 flows from a first bit line BL1 (i.e., the left side of the drawing) towards a word line WL (i.e., the right side of the drawing).

As illustrated in the part (A) of FIG. 10, in the SOT period, a potential difference VDD that places the switching element SEL1 in an ON state occurs between both ends of the wiring SOTL. By controlling the potential difference VDD, a write current Ic0 flows in the wiring SOTL. As a result of the write current Ic0 flowing in the wiring SOTL, a spin orbit torque that attempts to tilt the magnetization direction of the storage layer to the horizontal direction is generated. The spin orbit torque acts on the storage layer that is near to the wiring SOTL. Further, although not illustrated in FIG. 10, a bias magnetic field Hx in the X direction is applied to the storage layer.

Therefore, by the action of the spin orbit torque and the application of the bias magnetic field Hx, the magnetization direction of the storage layer is tilted in a direction which is approximately the horizontal direction and which has a component parallel to the magnetization direction of the reference layer.

Further, a potential difference Vg1 such that the reference layer side becomes a high potential relative to the storage layer side occurs between both ends of the magnetoresistive effect element MTJ. As a result, a positive VCMA effect occurs and the energy barrier Eb of the storage layer decreases. Therefore, the magnetization direction of the storage layer is quickly tilted by the assistance of the positive VCMA effect.

Next, as illustrated in the part (B) of FIG. 10, in the relaxation period, a potential difference does not occur between both ends of the wiring SOTL. As a result, the write current Ic0 stops and the action of the spin orbit torque also ceases. During the SOT period, the state of the storage layer transitions to the P state by exceeding the energy barrier Eb from the AP state. Therefore, in the relaxation period, the magnetization direction of the storage layer tilts to a more stable state in the P state (that is, a completely parallel state with respect to the magnetization direction of the reference layer).

Further, a potential difference Vg2 such that the reference layer side becomes a low potential relative to the storage layer side occurs between both ends of the magnetoresistive effect element MTJ. As a result, a negative VCMA effect occurs and the energy barrier Eb of the storage layer increases. Therefore, the magnetization direction of the storage layer is tilted more quickly by the assistance of the negative VCMA effect.

By the above-described operation, the magnetization direction of the storage layer is reversed to a direction parallel to the magnetization direction of the reference layer, and the operation for writing data “0” is completed.

### 1.2.6 Potential Difference Vg Application Patterns

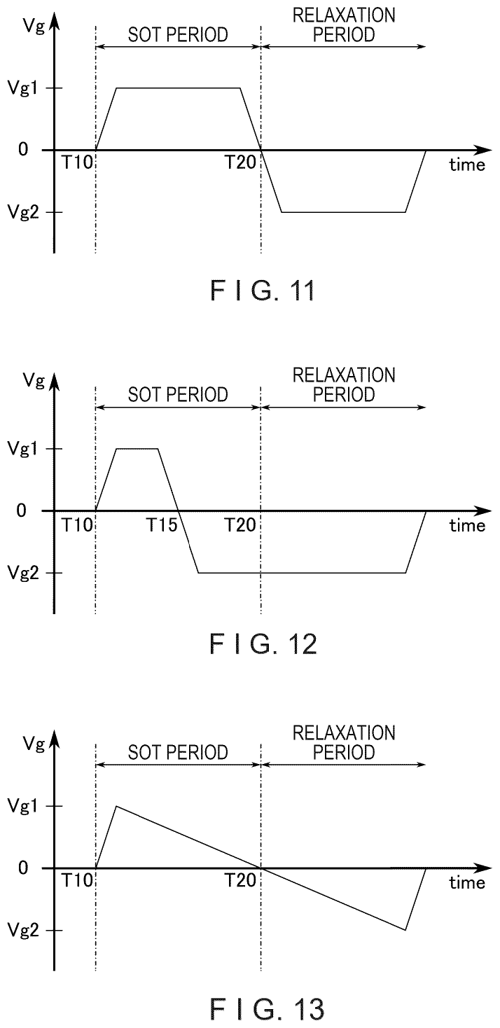

FIG. 11 is a waveform diagram illustrating a first example of a potential difference or voltage applied to the magnetoresistive effect element in a write operation performed by the magnetic memory device 1. FIG. 12 is a waveform diagram illustrating a second example of a potential difference or voltage applied to the magnetoresistive effect element in a write operation performed by the magnetic memory device 1. FIG. 13 is a waveform diagram illustrating a third example of a potential difference or voltage applied to the magnetoresistive effect element in a write operation performed by the magnetic memory device 1.

As illustrated in FIG. 11, for the potential difference Vg1, application may be started together with the start of the SOT period, and may be ended together with the end of the SOT period. For the potential difference Vg2, application may be started together with the start of the relaxation period, and may be ended together with the end of the relaxation period. The respective absolute values of the potential differences Vg1 and Vg2 may be equal to or different from each other.

As illustrated in FIG. 12, for the potential difference Vg1, application may be started together with the start of the SOT period, and the application may be ended at a time instant T15 (T10<T15<T20) during the SOT period. For the potential difference Vg2, application may be started together with the end of application of the potential difference Vg1 (at the time instant T15), and the application may be ended together with the end of the relaxation period.

As illustrated in FIG. 13, for the potential difference Vg1, application may be started together with the start of the SOT period. For the potential difference Vg2, the application may be ended together with the end of the relaxation period. Further, the potential difference may be continuously changed from the start of the application of the potential difference Vg1 until the end of the application of the potential difference Vg2.

### 1.3 Effects

In the magnetic memory device 1 described above, a writing method that utilizes spin orbit torque is adopted. In this case, after the magnetization direction of the storage layer is tilted in the horizontal direction in a SOT period, the magnetization direction is completely reversed in a relaxation period. In particular, because the magnetization direction is changed without depending on a spin orbit torque in the relaxation period, a long time period may be required until the magnetization direction reverses.

In a write operation, the write circuit 14 causes a write current to flow through the wiring SOTL in the SOT period. Further, in the relaxation period, the write circuit 14 stops the write current and applies a negative potential difference Vg2 to the one end with respect to the other end connected to the wiring SOTL of the magnetoresistive effect element MTJ. By this means, in the relaxation period, the energy barrier Eb of the storage layer can be significantly increased. Therefore, the magnetization direction of the storage layer which tilted in the horizontal direction in the SOT period can be quickly reversed. Hence, the write time can be shortened.

Further, the magnetization direction fluctuates under the influence of thermal disturbance. In some cases, such thermal disturbance may cause the magnetization direction of the storage layer that tilted horizontally in the SOT period to return to its original direction again. According to the embodiment, the energy barrier Eb of the storage layer can be significantly increased in the relaxation period. Therefore, it can be made difficult for the magnetization direction of the storage layer that tilted horizontally to then return again to the original direction thereof. Therefore, write errors can be reduced.

### 2. Modifications

The foregoing embodiments are merely examples, and various modifications can be applied thereto.

Although in the foregoing embodiments, the potential difference Vg1 is applied to the magnetoresistive effect element MTJ in the SOT period, embodiments are not limited to this example.

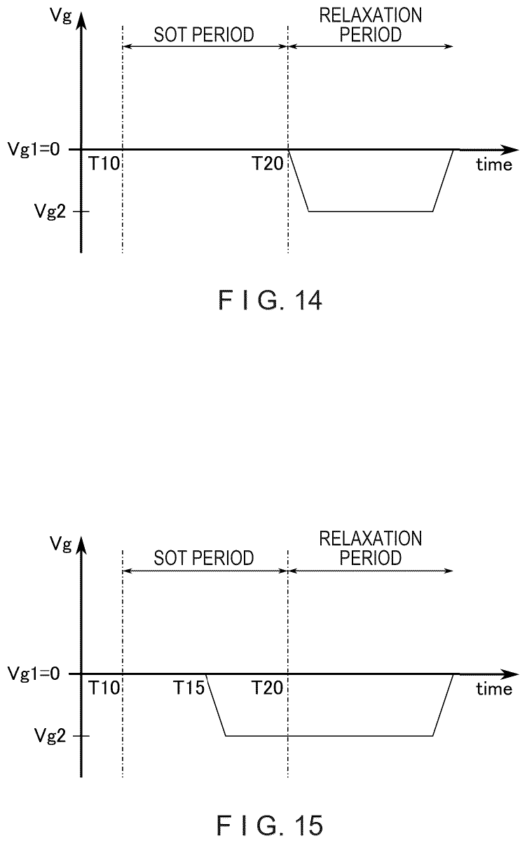

FIG. 14 is a waveform diagram illustrating a fourth example of a potential difference or voltage applied to the magnetoresistive effect element in a write operation performed by a magnetic memory device according to a modification. FIG. 15 is a waveform diagram illustrating a fifth example of a potential difference or voltage applied to the magnetoresistive effect element in a write operation performed by a magnetic memory device according to a modification. FIG. 14 and FIG. 15 correspond to FIG. 11 and FIG. 12, respectively.

As illustrated in FIG. 14 and FIG. 15, the potential difference Vg1 may be approximately equal to “0”. Making the potential difference Vg1 equal to “0” includes a case where an unintended noise such as voltage disturbances or fluctuations that occur during device operation is applied as a voltage. Even in such a case, shortening of the relaxation period and suppression of the occurrence of write errors in the relaxation period can be realized.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A magnetic memory device comprising:
a conductive layer;
a magnetoresistive effect element provided on the conductive layer and including a first end portion that contacts the conductive layer and a second end portion that is opposite to the first end portion; and
a control circuit configured to perform a write operation to write data into the magnetoresistive effect element, the write operation including:
in a first period, causing a current to flow in the conductive layer, and
in a second period subsequent to the first period, stopping the current and applying a negative voltage to the second end portion with respect to the first end portion.

2. The magnetic memory device according to claim 1, wherein the write operation includes applying a positive voltage to the second end portion with respect to the first end portion in the first period.

3. The magnetic memory device according to claim 2, wherein
the first period includes a first sub-period and a second sub-period subsequent to the first sub-period, and
the write operation includes, in the second sub-period and the second period, applying the negative voltage to the second end portion with respect to the first end portion.

4. The magnetic memory device according to claim 2, wherein, over the first and second periods, the positive voltage applied to the second end portion continuously changes to the negative voltage.

5. The magnetic memory device according to claim 1, wherein the write operation includes, in the first period, applying a voltage that is approximately equal to 0 to the second end portion.

6. The magnetic memory device according to claim 1, wherein
the first period has a first sub-period and a second sub-period subsequent to the first sub-period, and
the write operation includes:
in the first sub-period, applying a voltage that is approximately equal to 0 to the second end portion, and
in the second sub-period and the second period, applying the negative voltage to the second end portion.

7. The magnetic memory device according to claim 1, wherein
the write operation includes:
when writing first data, causing the current to flow in a first direction, and
when writing second data that is different from the first data, causing the current to flow in a second direction anti-parallel to the first direction.

8. The magnetic memory device according to claim 1, wherein the conductive layer contains at least one element selected from tantalum, tungsten, ruthenium, rhodium, palladium, silver, copper, osmium, iridium, platinum, gold, and manganese.

9. The magnetic memory device according to claim 1, wherein
the magnetoresistive effect element includes:
a first ferromagnetic layer in contact with the conductive layer,
a first nonmagnetic layer above the first ferromagnetic layer, and
a second ferromagnetic layer above the first nonmagnetic layer, and
the first nonmagnetic layer contains magnesium and oxygen.

10. The magnetic memory device according to claim 9, wherein the first ferromagnetic layer contains at least one element selected from cobalt, iron, and nickel.

11. The magnetic memory device according to claim 10, wherein the first ferromagnetic layer further contains at least one element selected from gold, silver, platinum, palladium, rhodium, iridium, ruthenium, and osmium.

12. The magnetic memory device according to claim 9, wherein the magnetoresistive effect element further includes:
a second nonmagnetic layer above the second ferromagnetic layer, and
a third ferromagnetic layer above the second nonmagnetic layer.

13. The magnetic memory device according to claim 12, wherein the second nonmagnetic layer contains at least one element selected from ruthenium, osmium, rhodium, iridium, vanadium, and chromium.

14. A method for performing a write operation to write data into a magnetic memory device that includes a conductive layer and a magnetoresistive effect element provided on the conductive layer and including a first end portion that contacts the conductive layer and a second end portion that is opposite to the first end portion, the method comprising:
in a first period, causing a current to flow in the conductive layer; and
in a second period subsequent to the first period, stopping the current and applying a negative voltage to the second end portion with respect to the first end portion.

15. The method according to claim 14, further comprising:
applying a positive voltage to the second end portion with respect to the first end portion in the first period.

16. The method according to claim 15, wherein
the first period includes a first sub-period and a second sub-period subsequent to the first sub-period, and
the method further comprises:
in the second sub-period and the second period, applying the negative voltage to the second end portion with respect to the first end portion.

17. The method according to claim 15, wherein, over the first period and the second period, the positive voltage applied to the second end portion continuously changes to the negative voltage.

18. The method according to claim 14, further comprising:
in the first period, applying a voltage that is approximately equal to 0 to the second end portion.

19. The method according to claim 18, wherein
the first period has a first sub-period and a second sub-period subsequent to the first sub-period, and
the method further comprises:
in the first sub-period, applying a voltage that is approximately equal to 0 to the second end portion with respect to the first end portion; and
in the second sub-period and the second period, applying the negative voltage to the second end portion with respect to the first end portion.

20. The method according to claim 14, further comprising:
when writing first data, causing the current to flow in a first direction; and
when writing second data that is different from the first data, causing the current to flow in a second direction anti-parallel to the first direction.
